(19) United States
(12) Patent Application Publication
(10) Pub. No.: US 2010/0279479 A1
(43) Pub. Date: Nov. 4, 2010

(54) Formation Of Raised Source/Drain On A Strained Thin Film Implanted With Cold And/Or Molecular Carbon

(75) Inventors: Christopher R. Hatem, Cambridge, MA (US); Helen L. Maynard, North Reading, MA (US); Deepak A. Ramappa, Cambridge, MA (US)

Correspondence Address: Varian Semiconductor Equipment Associates, 35 Dory Road, Gloucester, MA, 01930-2297, US

(73) Assignee: Varian Semiconductor Equipment Associates, Inc., Gloucester, MA (US)

(21) Appl. No.: 12/434,364

(22) Filed: May 1, 2009

(51) Int. Cl. H01L 21/30

(52) U.S. Cl. 438/300; 257/E21.211

(57) ABSTRACT

A method is disclosed for enhancing tensile stress in the channel region of a semiconductor structure. The method includes performing one or more cold-carbon or molecular carbon ion implantation steps to implant carbon ions within the semiconductor structure to create strain layers on either side of a channel region. Raised source/drain regions are then formed above the strain layers, and subsequent ion implantation steps are used to dope the raised source/drain region. A millisecond anneal step activates the strain layers and the raised source/drain regions. The strain layers enhances carrier mobility within a channel region of the semiconductor structure, while the raised source/drain regions minimize reduction in strain in the strain layer caused by subsequent implantation of dopant ions in the raised source/drain regions.

### BACKGROUND OF THE INVENTION

1. Field of the Invention

Embodiments of the invention relate to the field of stress enhancements in the source/drain regions of transistors. More particularly, the present invention relates to a method for forming raised source/drain regions on strained films that have been implanted with carbon.

2. Discussion of Related Art

Current flowing through an electric field in the channel region of a field effect transistor is proportional to the mobility of the carriers (e.g., electrons in n-type field effect transistors (n-FETs) and holes in p-type field effect transistors (p-FETs)) in the channel region. Different strains on the channel region can affect carrier mobility and, thus, current flow. For example, compressive stress on a channel region of a p-FET can enhance hole mobility. Tensile stress on a channel region of an n-FET can enhance electron mobility. A number of stress engineering techniques are known for imparting the desired stress on n-FET and p-FET channel regions. For example, a compressive stress (i.e., a uni-axial compressive strain parallel to the direction of the current) can be created in the channel region of a p-FET by forming the source/drain regions with an alloy of silicon (Si) and germanium (Ge). A tensile stress (i.e., a uni-axial tensile strain parallel to the direction of the current) may be created in the channel region of an n-FET by forming the source/drain regions with an alloy of Si and carbon (C).

A remaining problem, however, is the loss of strain caused by Source/Drain implantation steps performed subsequent to carbon implanation. For example, during NMOS manufacturing, formation of the strain layer (SiC) is followed by either a Phosphorus or Arsenic dopant implant in the Source/Drain regions, during which the region of doped SiC loses a significant portion of its strain. In addition, during formation of the strain layer (SiC), traditional carbon-implant techniques can result in defects in the Silicon substrate. If raised source/drain regions are subsequently grown over the strained SiC regions, these defects can be magnified, which can result in reduced overall yield.

Thus, there is a need for a method of efficiently imparting and maintaining strain in transistor structures that employ raised Source/Drain regions. Such a method should be simple, efficient, and should maximize device yields.

### SUMMARY OF THE INVENTION

A method is disclosed for enhancing stress in a channel region of a semiconductor device, comprising: providing a semiconductor structure comprising a silicon substrate having a channel region; forming strain layers within the semiconductor structure, the strain layers located on either side of the channel region, the strain layers formed by an ion-implantation step comprising cold carbon ion implantation or molecular carbon ion implantation; forming raised source/drain regions above the strain layers by depositing a silicon layer over each of the strain layers; doping the raised source/drain regions; and annealing the semiconductor structure to activate the raised source/drain regions.

A method is disclosed for enhancing stress in a source or drain region of a semiconductor device, comprising: providing a semiconductor structure; forming a plurality of strain layers within the semiconductor structure using a plurality of ion implantation steps comprising cold carbon ion implantation or molecular carbon ion implantation, the strain layers located on either side of a channel region of the structure; depositing a silicon layer over each of the plurality of strain layers to form a plurality raised source/drain regions above the strain layers; doping the plurality raised source/drain regions; and annealing the semiconductor structure using a millisecond annealing technique to activate the raised source/drain regions.

### BRIEF DESCRIPTION OF THE DRAWINGS

The accompanying drawings illustrate preferred embodiments of the disclosed method so far devised for the practical application of the principles thereof, and in which:

FIG. 1 is a schematic diagram of an exemplary ion implanter system;

FIG. 2 is a cross-section view of an exemplary transistor structure in which a raised source/drain region overlies an Si—C strained layer;

FIG. 3 is a flow chart describing an exemplary process flow for the disclosed method;

FIG. 4 is a graphical representations of the resultant strain from ion implantation, and the loss of strain subsequent to dopant implantation;

FIG. 5 is a graphical representation showing strain as a function of depth in a semiconductor structure;

FIG. 6 is a graphical representation showing strain as a function of depth in a semiconductor structure; and

FIGS. 7A and 7B are cross-sections showing the interface between substrate materials and exemplary raised source/drain regions.

### DESCRIPTION OF EMBODIMENTS

A technique is disclosed for combating the aforementioned loss of strain problem is to grow a raised Source/Drain (S/D) on top of the Si—C layer. Cold ion implantation of carbon and/or molecular carbon ion implantation enable the creation of an Si—C layer that can then be used as the base for a raised S/D. And since the S/D are raised above the Si—C layer, subsequent implantation of dopant ions (e.g., P, As) in the raised S/D regions has less impact on the strain layer (i.e., the dopant implant will not relax the strain layer) as compared to implants in the C-containing regions. In addition, the use of cold implantation of carbon results in a substrate surface having fewer defects than is found using traditional carbon implantation techniques, thus resulting in a better surface upon which to subsequently grow the raised S/D regions.

The disclosed technique includes a single or series of carbon ion implants at a reduced temperature and/or using molecular carbon with or without the substrate at reduced temperatures. The substrate is then annealed to form the strained film. A raised S/D is then formed on top of the strained film. The disclosed technique is novel in that it uses a combination of a strained layer formed with cold and/or carbon implantation and a raised source drain to preserve strain in the channel while adding the conductive dopant to the transistor. The technique enables ion implantation techniques to be used on ever smaller sizes of NMOS transistors.

As will be appreciated, the disclosed technique may provide an additional benefit in that the separate creation of the strain and dopant layers may make it possible to optimize the processing of each layer, including lateral placement of ions, and thermal processing (i.e., annealing).

Ion implantation refers generally to the process of depositing chemical species into a substrate by direct bombardment of the substrate with energized ions. In semiconductor manufacturing, ion implanters are often used for doping processes that alter the type and level of conductivity of target materials. A precise doping profile in an integrated circuit substrate and its thin-film structure may be used to achieve desired device performance. To obtain a desired doping profile, one or more ion species may be implanted in different doses and at different energy levels. Low temperature ion implantation refers to processes in which the substrate (wafer) to be implanted is cooled during the implantation process to a temperature range of about +15 to −100° C. Exemplary techniques for pre-cooling a wafer prior to ion implantation are described in U.S. patent application publications 2008/0044938, 2008/0121821, and 2008/0124903, which are incorporated by reference herein in their entirety.

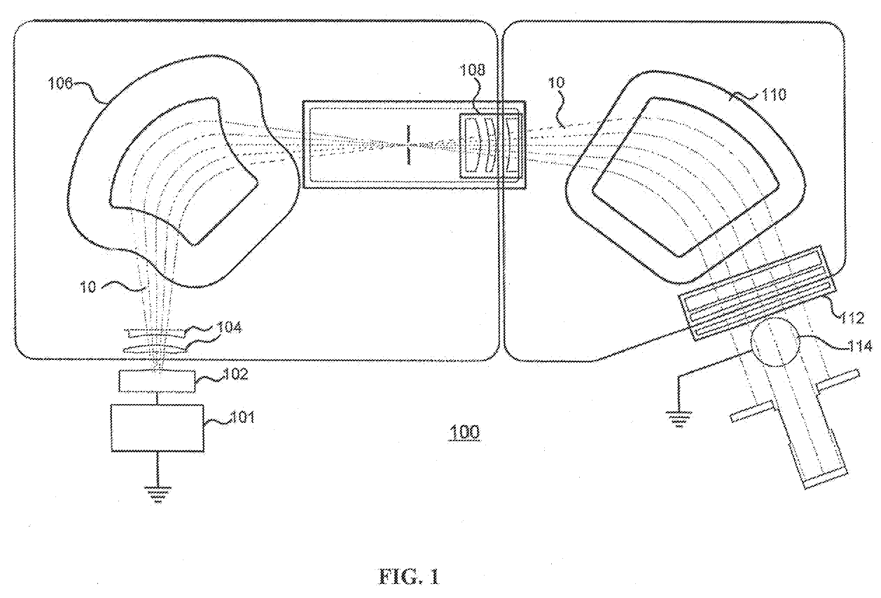

An exemplary ion implanter system 100 is illustrated in FIG. 1. At the outset it will be appreciated that system 100 is but one of a variety of ion implanter systems that may be used to implement the disclosed method, and that the disclosed method is not in any way limited in its application to the specifics of the illustrated system. Thus, any type of ion implanter or plasma-based may be used, as long as it is capable of implanting greater than 1×10¹⁵ doses (ions/cm²), and energies between 200 and 20,000 eV. Further, the system may or may not include mass filtering.

The illustrated ion implanter system 100 is housed in a high-vacuum environment. The ion implanter system 100 may comprise an ion source 102, biased to a potential by power supply 101, and a series of beam-line components through which an ion beam 10 passes. The series of beam-line components may include, for example, extraction electrodes 104, a 90° magnet analyzer 106, a first deceleration (D1) stage 108, a 70° magnet collimator 110, and a second deceleration (D2) stage 112. Much like a series of optical lenses that manipulate a light beam, the beam-line components can filter and focus the ion beam 10 before steering it towards a target wafer. During ion implantation, the target wafer is typically mounted on a platen 114 that can be moved in one or more dimensions (e.g., translate, rotate, and tilt) by an apparatus, sometimes referred to as a “roplat.”

The ion implanter system 100 may also include a system controller 116 programmed to control one or more the components of the system 100. The system controller 116 may be connected to, and in communication with, some or all of the aforementioned system components. For example, the system controller 116 may adjust the energy with which the ions are implanted to obtain a desired depth of implantation. The system controller 116 may include a processor 118 executing instructions for performing one or more steps of the disclosed method.

Although not shown, the system 100 may further include a substrate cooling section for holding the substrate at a desired temperature prior to, or during, the implantation process. Substrate cooling may be used in combination with the implantation of molecular carbon. This may be particularly advantageous where the molecular carbon implant dose is relatively low.

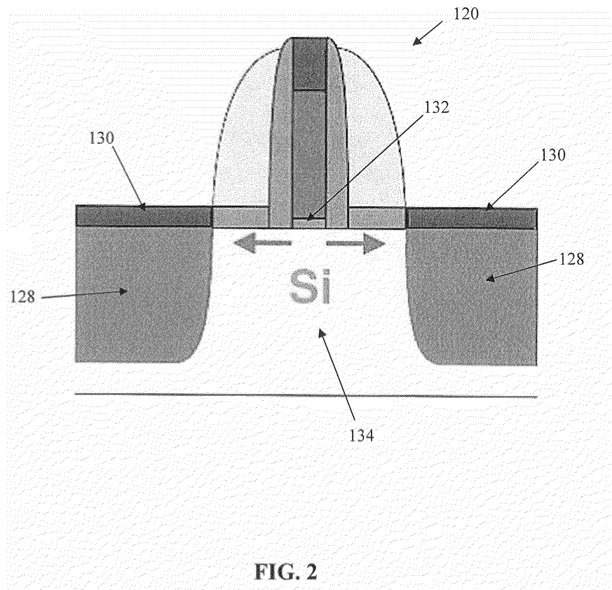

Referring now to FIG. 2, a cross-section of an exemplary semiconductor structure 120 is illustrated comprising a substrate 122, strain (i.e., carbon-containing) layers 128, raised S/D regions 130 overlying the strain layers 128, a gate region 132 and a channel region 134. The strain layers 128 (effectively the S/D regions of the transistor), may be provided in a variety of thicknesses and areas, depending upon the technology “node” (i.e., milestone). For example, in a 32 nanometer (nm) CMOS node, the thickness of the strain layers 128 can be from about 40 to about 140 nm. The raised S/D layers typically are about 25-30% of this value, but they may be thicker depending on other needs the raised S/D may be serving. A raised S/D scheme in the 32 nm node would be equal to or less than about 30-40 nm. This value may be thicker, however, if the silicide consumption of silicon is high.

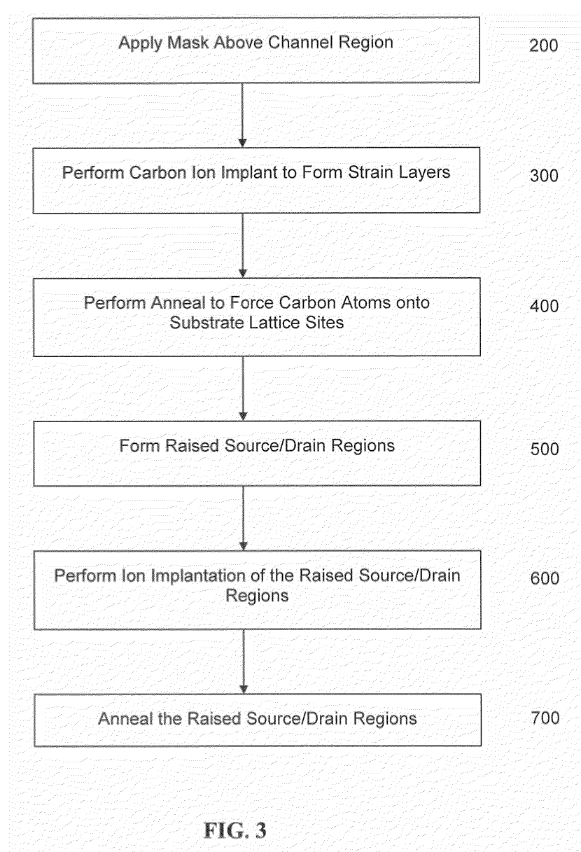

Referring to FIG. 3, a process for forming the structure of FIG. 2 will be described. At step 200, a semiconductor substrate is provided, and a mask layer (not shown) applied above a designated channel region 134. The mask layer is provided to prevent subsequent implantation of carbon ions into the channel region.

At step 300, carbon ions are implanted into the substrate 122 using a low-temperature ion implantation technique and/or a molecular carbon implantation technique. The implantation step may employ an implantation energy sufficient to place the carbon ions at a desired depth within the substrate. As noted, step 300 can include multiple ion implantation steps. Where multiple implantation steps are used, the energy level and/or implantation time may be varied between the different steps to achieve a desired final implant profile in the semiconductor structure.

It will be appreciated that the carbon-implantation steps should be performed in a manner that results in strain layers 128 that are closely adjacent to the channel region 134 so as to maximize strain on the channel carriers. Maximizing strain on the channel results in enhanced electron mobility in the channel region, thus enhancing conductivity.

Once the carbon implantation process is complete, the structure may be annealed at step 400 to cause the implanted carbon ions to take positions on the Si substrate lattice, thereby inducing a desired stress. The annealing step also ensures that the carbon ions will remain on the lattice rather than precipitating. Step 400 may comprise one or more annealing steps. The annealing steps may comprise millisecond anneal steps, which may include spike annealing, laser annealing and/or flash annealing. Examples of other appropriate anneal types include a solid phase epitaxy anneal, which is often a relatively long, low temperature anneal. The criterion for an acceptable anneal process is that recrystallization should be faster than the average time it takes an atom to diffuse to another implanted ion, forming precipitates. This is a function of the implanted dose, temperature, time and diffusivities of the ions in the amorphous and crystalline material.

In one embodiment, the annealing step (step 400) is not performed immediately subsequent to the carbon ion implantation step (step 300). Instead, a single annealing step may be performed subsequent to forming and doping the raised S/D regions (see step 700, below). This single annealing step may be used to activate the S/D regions and cause the implanted carbon ions in the strain layers to take positions on the Si substrate lattice to induce a desired stress.

At step 500, the raised S/D regions are formed. Exemplary processes for forming the raised S/D regions may comprise: (1) chemical vapor deposition (CVD) of doped/undoped silicon on top of the S/D regions, (2) epitaxial growth of silicon, (3) atomic layer deposition (ALD) of silicon, or (4) plasma vapor deposition (PVD) of silicon.

At step 600, the raised S/D regions are doped using an ion implantation step that implants one or more dopant material(s) into the raised S/D regions 130 on either side of the gate region 132, and above the strain layers 128. Examples of appropriate dopants include As, P and Antimony (Sb). During this implantation process, the channel region 134 is again masked to minimize the presence of dopant ions in the channel region 134.

At step 700, the raised S/D regions 130 may be activated using one or more annealing steps. One or more of these annealing steps can be millisecond anneal steps, including laser annealing or flash annealing, solid-phase epitaxy and/or RTP spike anneals.

As an alternative to the identified annealing procedure (i.e., where separate annealing steps are used to anneal the strain layer and the raised S/D regions), all annealing step(s) can be performed after the raised S/D regions are formed and doped. This technique may result in a more efficient overall process while still imparting the desired strain in strain layer 128.

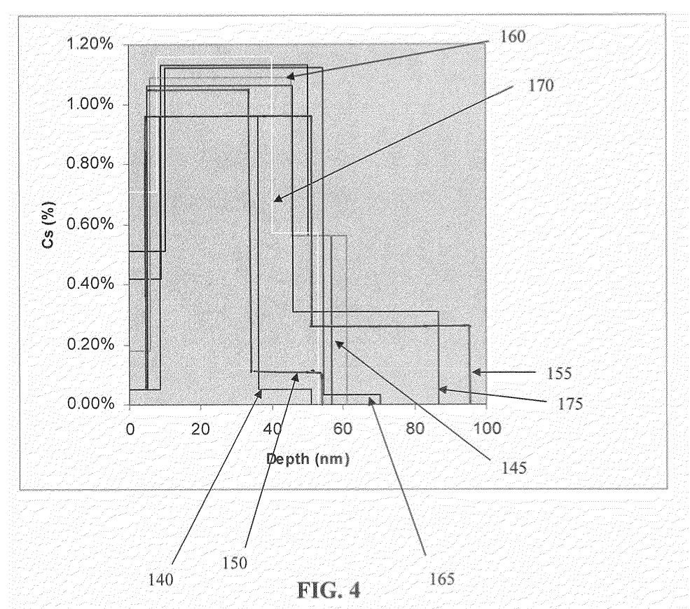

FIG. 4 is an exemplary strain plot showing %-strain as a function of depth in strain layers 128 for a variety of different strain-inducing implant ions and combinations of strain-inducing implant ions. In the illustrated plot, “Cs” is the carbon substitutional concentration (the Y axis). The lateral strain in the channel region of a transistor is proportional to this concentration. The X-axis is depth into the transistor.

FIG. 4 indirectly illustrates the profile of strain distribution in the channel region moving along the cross section of a transistor. The plot shows how strain can be built into a substrate to a depth of about 60 nm for various implant candidates (e.g., Carbon-800, Cold Carbon-900, Ethane-1000, Cold Ethane-1100, Germanium-Carbon-1,200, Germanium-Cold Carbon-1300, Germanium-Ethane-1400, Germanium-Cold-Ethane-1500).

As can be seen, a strain layer can be formed by implanting various ions and ion combinations into a substrate followed by recrystallization (i.e., annealling) to achieve high levels of strain in the structure. Typically, however, additional processing steps must be performed on the structure in order to build a completed device. For example, when the S/D regions are subsequently implanted with dopant and spike annealed, strain in the strain layer can be substantially reduced, which can impact the effectiveness of the strain layer.

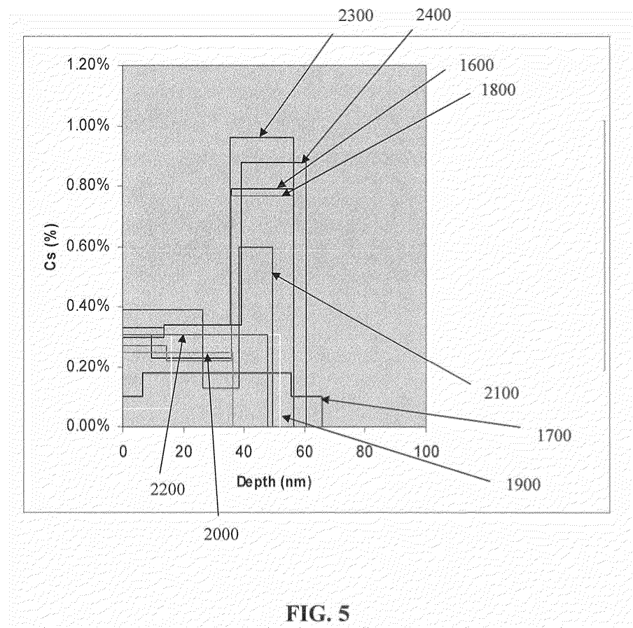

FIG. 5 is an exemplary strain plot illustrating loss of strain in the strain layer 128 after implantation of dopant. As compared to FIG. 4, FIG. 5 shows how strain in the strain layer 128 is affected for specific combinations of strain layer implants and S/D region implants. In FIG. 5, the S/D regions were doped with Phosphorus (e.g., Ge—C—P-1600, C—P-1700, GE-Cold C—P-1800, GE-Ethane-P-1900, Ethane-P-2000, GE-Cold Ethane-P-2100, Cold Ethane-P-2200, GE-Hi C—P-2300, Ge-Cold Hi C—P-2400).

As can be seen, with the addition of Phosphorus, Cs (and thus strain) is significantly reduced. For example, comparing the first dataset in FIG. 4 (labeled “C”-800) to the second dataset in FIG. 5 (Labeled “C-P”-1700), it can be seen that the substitutional carbon concentration (analogized to strain) in the region of 0-35 nm depth is reduced from about 1% to about 0.3%.

The disclosed method reduces the impact that such dopant ions have on the strain in the strain layer 128. With the disclosed method, placing dopant ions (e.g., Phosphorus) in the raised S/D regions 130 results in less dopant ions in the strain layer 128, and as a result, higher strain levels can be maintained in the strain layer. This, in turn, results in greater channel carrier mobility and current flow.

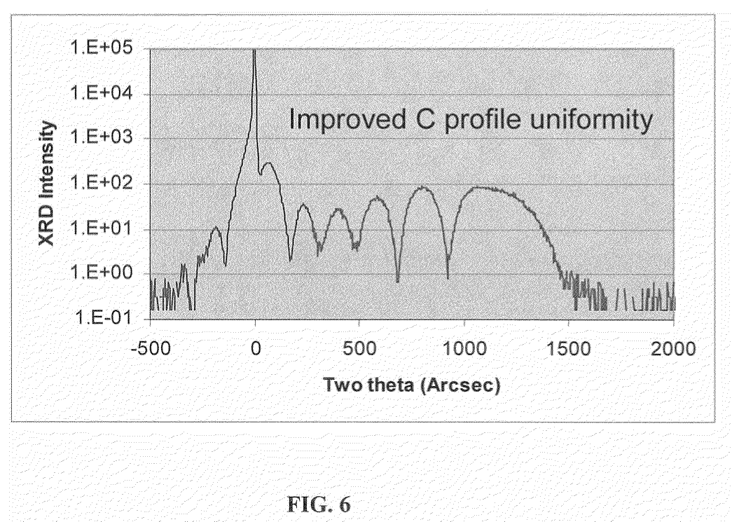

FIG. 6 shows a high resolution XRD rocking curve showing a thick layer of Si:C with a relatively high level of substitutional carbon that has a good interface with the underlying Si substrate. This figure shows that a high-quality SiC layer can be produced (i.e., one that is as good or better than a layer built using epitaxial techniques) using the disclosed method.

The disclosed method, which employs a cold implantation of C ions followed by the formation of raised S/D regions, maximizes the amount of C atoms that reside on the Si substrate lattice and reduces overall damage to the substrate caused by the implantation process. When forming a strain layer using C, it is advantageous to dislodge as many Si atoms as possible to maximize the number of C atoms that can occupy Si lattice sites. Cold implantation techniques lead to more thorough amorphization of the substrate (i.e., more Si atoms are dislodged and can be replaced by C atoms), as compared to other implant techniques. After annealing, cold implanted substrates show less residual damage because defects such as vacancies, unoccupied sites, etc., have a greater chance of being filled during recrystallization (i.e., annealing), since a larger concentration of C atoms are present due to the cold implant. As a result, not only are the number of defects in the Si substrate reduced, but the substrate surface also “heals” better during the annealing step(s), thus enhancing the smoothness of the surface on which the subsequent raised S/D regions may be formed.

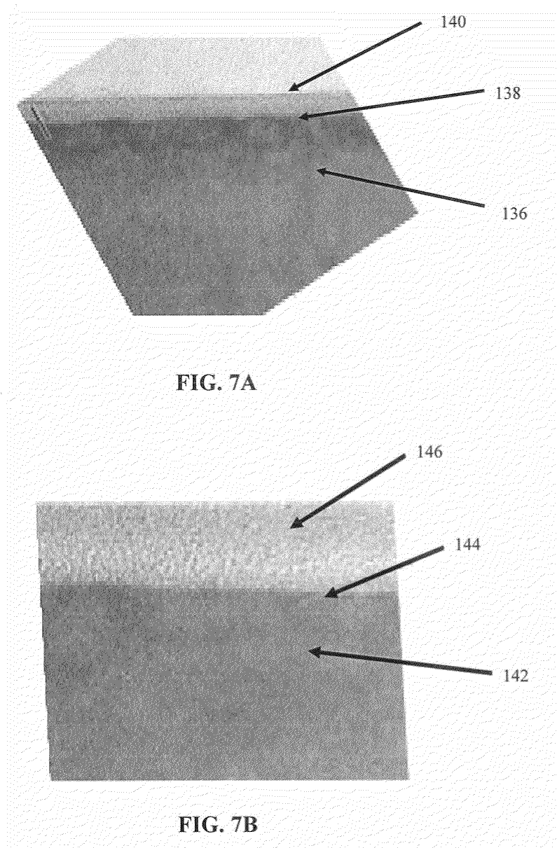

With prior techniques, the large numbers of defects in the Si substrate induced by the implantation step can be compounded during subsequent epitaxial formation of the overlying raised S/D regions. This, in turn, can result in an undesirably reduced overall yield. Referring to FIG. 7A, an exemplary substrate 136, implanted using prior techniques, is shown having an uneven upper surface 138 forming the interface between the substrate 136 and the exemplary raised S/D region 140. Referring now to FIG. 7B, an exemplary substrate 142 processed using the disclosed method is shown. The upper surface 144 of the substrate is substantially smoother, with fewer defects, thus forming a better interface between the substrate 142 and the raised S/D region 146. Since the implanted Si substrate has a smoother surface, a better interface is formed between the substrate 142 and the raised S/D regions 146, which thus results in better raised S/D quality and device yield.

It will be appreciated that in addition to inducing strain in strain layer 128, carbon ions may provide an additional benefit in that they can act as a diffusion barrier to phosphorous (P) when P is used as the dopant in raised S/D regions 130. P has desirable properties as a dopant (e.g., low sheet resistance Rₛ), but it also has a propensity to diffuse throughout the materials in which it is implanted. It is desirable to minimize dopant diffusion in order to minimize negative effects such as short-channel effects and leakage. As a result, arsenic (As) has often been used as a dopant in lieu of P because As does not have the same tendency to diffuse. Using C in the strain layer 128, however, enables the use of P in the dopant layer without the aforementioned diffusion. Since lower sheet resistances can be achieved with P than with As, P is more desirable for use in the raised S/D regions 130.

The method described herein may be automated by, for example, tangibly embodying a program of instructions upon a computer readable storage media capable of being read by machine capable of executing the instructions. A general purpose computer is one example of such a machine. A non-limiting exemplary list of appropriate storage media well known in the art would include such devices as a readable or writeable CD, flash memory chips (e.g., thumb drives), various magnetic storage media, and the like.

While the present invention has been disclosed with reference to certain embodiments, numerous modifications, alterations and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

The functions and process steps herein may be performed automatically or wholly or partially in response to user command. An activity (including a step) performed automatically is performed in response to executable instruction or device operation without user direct initiation of the activity.

The systems and processes of FIGS. 1-3 are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. The processes and applications may, in alternative embodiments, be located on one or more (e.g., distributed) processing devices accessing a network linking the elements of FIG. 1. Further, any of the functions and steps provided in the Figures may be implemented in hardware, software or a combination of both and may reside on one or more processing devices located at any location of a network linking the elements of FIG. 1 or another linked network, including the Internet.

What is claimed is:

1. A method for forming an semiconductor device having raised source/drain regions, comprising:
providing a semiconductor structure comprising a silicon substrate having a channel region;
forming strain layers within the semiconductor structure, the strain layers located on either side of the channel region, the strain layers formed by an ion-implantation step comprising cold carbon ion implantation or molecular carbon ion implantation;
forming raised source/drain regions above the strain layers by depositing a silicon layer over each of the strain layers;
doping the raised source/drain regions; and
annealing the semiconductor structure to activate the raised source/drain regions.

2. The method of claim 1, wherein the step of forming strain layers comprises a plurality of ion implantation steps.

3. The method of claim 2, wherein the cold-ion implantation step is performed at a temperature of from about +15° C. to −100° C.

4. The method of claim 2, wherein the ion implantation step comprises an ion implant technique using molecular carbon.

5. The method of claim 1, wherein the doping step comprises implanting ions comprising at least one of Phosphorus, Arsenic and Antimony in to the raised source/drain regions.

6. The method of claim 1, further comprising performing a strain layer annealing step after to the step of forming strain layers and before the step of depositing a silicon layer over each of the strain layers.

7. The method of claim 6, wherein the strain layer annealing step comprises a millisecond anneal technique.

8. The method of claim 6, wherein the step of annealing the semiconductor structure to produce a strain in the strain layer comprises a plurality of annealing steps.

9. The method of claim 1, wherein the step of annealing the semiconductor structure to activate the raised source/drain regions comprises a millisecond anneal technique.

10. The method of claim 1, wherein the step of forming strain layers comprises an plurality of ion implantation steps implanting C ions at differing depths within the substrate.

11. A method for forming a semiconductor device having raised source/drain regions, comprising:
providing a semiconductor structure;
forming a plurality of strain layers within the semiconductor structure using a plurality of ion implantation steps comprising cold carbon ion implantation or molecular carbon ion implantation, the strain layers located on either side of a channel region of the structure;
depositing a silicon layer over each of the plurality of strain layers to form a plurality raised source/drain regions above the strain layers;
doping the plurality raised source/drain regions; and
annealing the semiconductor structure using a millisecond annealing technique to activate the raised source/drain regions.

12. The method of claim 11, wherein the step of forming a plurality of strain layers comprises a plurality of ion implantation steps.

13. The method of claim 11, wherein the cold-ion implantation step is performed at a temperature of from about +15° C. to −100° C.

14. The method of claim 11, wherein the ion implantation step comprises an ion implant technique using molecular carbon.

15. The method of claim 11, wherein the doping step comprises implanting ions comprising at least one of Phosphorus, Arsenic and Antimony in to the raised source/drain regions.

16. The method of claim 11, further comprising performing a strain layer annealing step after to the step of forming a plurality of strain layers and before the step of depositing a silicon layer over each of the strain layers.

17. The method of claim 16, wherein the strain layer annealing step comprises a millisecond anneal technique.

18. The method of claim 16, wherein the strain layer annealing step comprises a plurality of annealing steps.

19. The method of claim 11, wherein the step of annealing the semiconductor structure to activate the raised source/drain regions comprises a millisecond anneal technique.

20. The method of claim 11, wherein the step of forming a plurality of strain layers comprises an plurality of ion implantation step implanting C ions at differing depths within the semiconductor structure.
